(19) United States
(12) Patent Application Publication
(10) Pub. No.: US 2022/0358946 A1
(43) Pub. Date: Nov. 10, 2022

(54) SPEECH PROCESSING APPARATUS AND METHOD FOR ACOUSTIC ECHO REDUCTION

(71) Applicant: British Cayman Islands Intelligo Technology Inc., Grand Cayman (KY)

(72) Inventors: CHAO-JUNG LAI, Zhubei City (TW); YI-TANG LIN, Zhubei City (TW); TSUNG-LIANG CHEN, Zhubei City (TW)

(21) Appl. No.: 17/539,574

(22) Filed: Dec. 1, 2021

Related U.S. Application Data
(60) Provisional application No. 63/186,072, filed on May 8, 2021.

(51) Int. Cl. G10L 21/034; G10L 21/0208

(52) U.S. Cl. CPC G10L 21/034; G10L 21/0208; G10L 2021/02082

(57) ABSTRACT

A speech processing apparatus applied in a communication device having a mechanical defect is disclosed. The apparatus comprises an acoustic echo cancellation (AEC) unit, a multiplier and a processor. The AEC unit cancels an echo in a first audio signal from a microphone using a known AEC algorithm to generate a second audio signal. The multiplier multiplies corresponding M frames of a downlink audio signal by a gain to provide a gained downlink signal for a speaker. The processor performs operations comprising: muting an uplink audio signal when a first power level for M frames of a first input signal is less than a first threshold value; and, reducing the gain when the first power level and a second power level for M frames of a second input signal are respectively greater than the first threshold value and a second threshold value.

### CROSS-REFERENCE TO RELATED APPLICATION

This application claims priority under 35 USC 119(e) to U.S. provisional application No. 63/186,072, filed on May 8, 2021, the content of which is incorporated herein by reference in its entirety.

### BACKGROUND OF THE INVENTION

### Field of the Invention

The invention relates to speech processing, and more particularly, to a speech processing apparatus and method for acoustic echo reduction.

### Description of the Related Art

Acoustic echo originates in a local audio loop back that occurs when a microphone picks up audio signals from a speaker, and sends it back to a far-end talker/user. The far-end talker will then hear the echo of his own voice as he speaks. The goal of acoustic echo cancellation/reduction is to reduce/cancel acoustic echoes in a microphone signal and then send the clean microphone signal to the far-end talker, thereby to improve the quality and intelligibility of microphone signals or dialog. In actual implementations, the performance of Acoustic Echo Cancellation (AEC) highly depends on mechanical designs of communication devices. For the communication devices, poor mechanical designs or mechanical defects, such as gasket leaks or proximity of microphones to speakers, are very likely to cause acoustic echoes. Even with the AEC function, it is difficult for the communication devices with the mechanical defects to improve the speech quality.

As well known in the art, an acoustic path in the communication device guides external sound to the microphone and must not have leaks (such as a gasket leak) that can cause multi-path echo or noise problems. A gasket is made of acoustically opaque material that prevents sound from passing through it. Common gasket materials include various kinds of rubber and compressible, closed-cell foams. The gasket must seal completely to a product case/housing and to the microphone or the printed circuit board (PCB). A leak in gasket seal allows the speaker output or other noise to propagate inside the product case into the microphone port. In some cases that the mechanical designs or gasket designs are not allowed to be modified, the multi-path echo or noise problems still need to be solved.

What is needed is a speech processing apparatus and method for acoustic echo reduction applicable to communication devices with mechanical defects that cause strong acoustic echoes.

### SUMMARY OF THE INVENTION

In view of the above-mentioned problems, an object of the invention is to provide a speech processing apparatus capable of reducing acoustic echoes for a communication device having a mechanical defect that causes strong acoustic echoes.

One embodiment of the invention provides a speech processing apparatus in a communication device having a mechanical defect apparatus is disclosed. The apparatus comprises an acoustic echo cancellation (AEC) unit, a multiplier and a processor. The AEC unit cancels an echo in a first audio signal from a microphone using a known AEC algorithm to generate a second audio signal. The multiplier multiplies a gain by corresponding M frames of a downlink audio signal to provide a gained downlink signal for a speaker. The processor performs a set of operations comprising: muting an uplink audio signal when a first power level for M frames of a first input signal associated with the second audio signal is less than a first threshold value; and, reducing the gain when the first power level and a second power level for M frames of a second input signal associated with the downlink audio signal are respectively greater than or equal to the first threshold value and a second threshold value, where M>=1.

Another embodiment of the invention provides a speech processing method applicable to a communication device having a mechanical defect, comprising: cancelling an echo in a first audio signal from one or more microphones using a known AEC algorithm to generate a second audio signal; muting an uplink audio signal when a first power level for M frames of a first input signal associated with the second audio signal is less than a first threshold value; reducing a gain when the first power level and a second power level for M frames of a downlink audio signal are respectively greater than or equal to the first threshold value and a second threshold value; and, multiplying the gain by corresponding M frames of the downlink audio signal to provide a gained downlink signal for a speaker, where M>=1.

Further scope of the applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 is a schematic diagram showing a speech processing apparatus according to an embodiment of the invention.

FIG. 2 is a flow chart showing a decision method according to an embodiment of the invention.

FIG. 3 is a schematic diagram showing a speech processing apparatus according to another embodiment of the invention.

### DETAILED DESCRIPTION OF THE INVENTION

As used herein and in the claims, the term “and/or” includes any and all combinations of one or more of the associated listed items. The use of the terms “a” and “an” and “the” and similar referents in the context of describing the invention are to be construed to cover both the singular and the plural, unless otherwise indicated herein or clearly contradicted by context. Throughout the specification, the same components with the same function are designated with the same reference numerals.

The invention deals with strong acoustic echoes caused by a mechanical defect of a communication device. A feature of the invention is to mute a uplink audio signal TX when the power level Pt of the uplink audio signal TX is less than a first threshold value TH1 to prevent a far-end talker from hearing his acoustic echoes. Another feature of the invention is to reduce the magnitude of a downlink audio signal RX or the volume of the speaker when Pt>=TH1 and the power level Pr of the downlink audio signal RX is greater than or equal to a second threshold value TH2; thus, the magnitudes of the echo signals received by the microphones would be reduced and the residual echo signals contained in the input audio signal S1 are easily eliminated by the AEC unit 130.

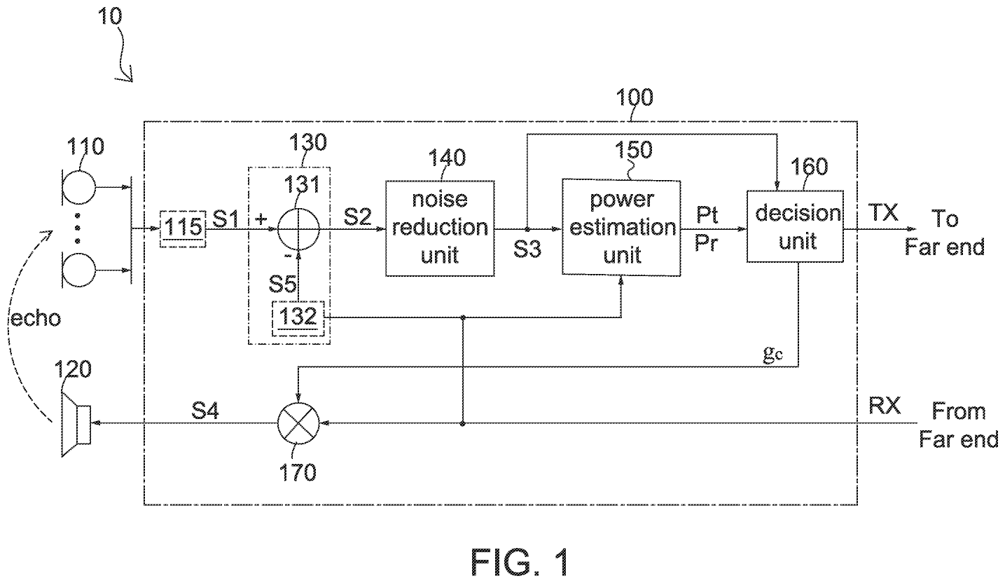

FIG. 1 is a schematic diagram showing a speech processing apparatus according to an embodiment of the invention. Referring to FIG. 1, a speech processing apparatus 100 of the invention, applicable to a communication device 10 with a mechanical defect, includes a pre-processing unit 115, an AEC unit 130, a noise reduction (NR) unit 140, a power estimation unit 150, a decision unit 160 and a multiplier 170. The communication device 10 can be a mobile phone, a personal digital assistant, a notebook computer, a sound recorder, headsets, and the like or some other communication device that can receive and output audio signals. The communication device 10 includes the speech processing apparatus 100, one or more microphones 110 and one speaker 120. The mechanical defect that causes strong acoustic echoes includes, without limitation, gasket leaks and the proximity of the microphones 110 to the speaker 120. In general, if the microphones 110 are disposed closely to the speaker 120, echo problems can be fixed by a mechanical design change. In addition to the proximity of the microphones 110 to the speaker 120, echo problems are mostly likely caused by a gasket leak or a poor gasket seal. An easy way to test for the gasket leak is to block the microphone port in the product case and play the speaker. If the echo problems remain, then the echo is likely caused by the gasket leak and can be fixed by a gasket design change. However, in some cases that the mechanical design or the gasket design are not allowed to be modified and the result of the gasket leak test indicates the power ratio of (P1/P2) is greater than Q, the speech processing apparatus 100/300 of the invention is provided to deal with the echo problems, where P1 denotes the power level of a downlink audio signal RX with a unsealed microphone port and P2 denotes the power level of the downlink audio signal RX with a sealed microphone port. In one embodiment, Q=10˜100 dB. Please note that the Q value is provided by example and not limitations of the invention.

The speech processing apparatus 100 receives one or more microphone signals from the one or more microphones 110. The components contained in the pre-processing unit 115 vary according to the type and the number of microphones 110. For example, if there is only one microphone 110 that outputs an analog audio signal, the pre-processing unit 115 is an analog to digital converter (ADC) configured to convert the analog audio signal into a digital audio signal S1; if there are multiple microphones 110 that output multiple analog audio signals, the pre-processing unit 115 includes multiple ADCs (coupled to the multiple microphones 110) and one average unit, and the average unit is configured to average the output signals from the ADCs to generate the digital audio signal S1; if there are multiple microphones 110 that output multiple digital audio signals, the pre-processing unit 115 includes one average unit configured to average multiple digital audio signals from the multiple microphones 110 to generate one digital audio signal S1; if there is only one microphone 110 that outputs the digital audio signal S1, the pre-processing unit 115 would be eliminated. Thus, the preprocessing unit 115 is optional and represented by dash lines in FIG. 1.

The AEC unit 130, the multiplier 170 and the pre-processing unit 115 may be implemented by software, hardware, firmware, or a combination thereof. An example of a pure solution would be a field programmable gate array (FPGA) design or an application specific integrated circuit (ASIC) design. The AEC unit 130 is configured to cancel acoustic echoes in the digital audio signal S1 by any well-known AEC algorithms or architecture to generate an echo-cancelled signal S2. In one embodiment, the AEC unit 130 includes a subtracter 131 only. In this embodiment, the subtracter 131 subtracts the downlink audio signal RX from the digital audio signal S1 to generate an echo-cancelled signal S2.

In an alternative embodiment, the AEC unit 130 includes a subtracter 131 and an adaptive filter 132. In practice, the speaker 120 can originate one or more echo signals, and each echo signal may traverse a direct or reflected path from the speaker 120 to the microphones 110; besides, the higher the volume of the speaker 120, the larger the magnitudes of the echo signals. To cancel the echo signals in the microphone channel, the adaptive filter 132 is placed in parallel to the echo paths between the downlink audio signal RX and the audio signal S1 with the downlink audio signal RX as a reference. The adaptive filter 132 has the ability to adjust its impulse response to filter out the correlated signal in the downlink audio signal RX and forms replicas of the echo paths such that the output signal S5 of the adaptive filter 132 are replicas of the echo signals. Since the operations of the adaptive filter 132 are well known in the art, its detailed descriptions are omitted herein. The subtracter 131 subtracts the echo replica signal S5 from the digital audio signal S1 to generate an echo-cancelled signal S2. Because the adaptive filter 132 is optional, it is represented by dashed lines in FIG. 1.

The NR unit 140 is configured to reduce noise in the echo-cancelled signal S2 by any well-known NR algorithms, such as traditional NR algorithms or artificial intelligence NR (AI-NR). For traditional NR algorithms, noise can be reduced in either time domain or frequency domain: (1) time domain: an infinite impulse response (IIR) filtering operation is performed over the echo-cancelled signal S2 in time domain to obtain a noise-reduced signal S3; (2) frequency domain: noise contained in multiple frequency bands in the echo-cancelled signal S2 is filtered out in frequency domain to obtain the noise-reduced signal S3. For AI-NR, a machine learning model (implemented using a recurrent neural network or a convolutional neural network) is trained to classify each of multiple frequency bands contained in the echo-cancelled signal S2 as “speech-dominant” or “noise-dominant (or non-speech)”, and then the noise in the frequency bands classified as “noise-dominant (or non-speech)” in the echo-cancelled signal S2 is eliminated in frequency domain to obtain a noise-reduced signal S3.

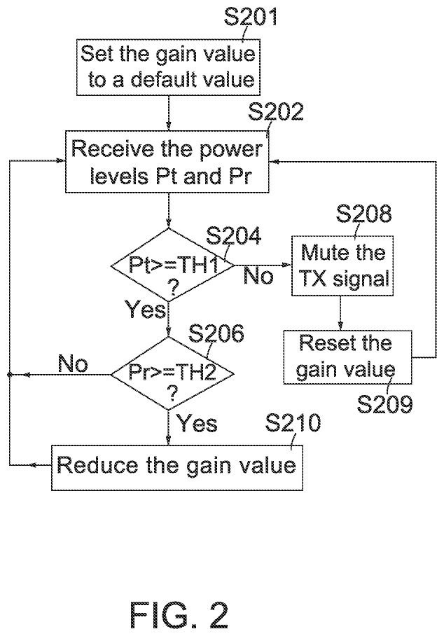

Next, the power estimation unit 150 respectively calculates/estimates a power level Pt per M frames of the noise-reduced signal S3 and a power level Pr per M frames of the downlink audio signal RX according to the following power equation:

$$P = \frac{1}{N} {\sum }_{n = 0}^{N - 1} {x ( n )}^{2} ,$$

where x(n) denotes a discrete audio signal and N denotes the number of samples in M frames of the discrete audio signal x(n). N is a power of two, such as 128, 256 or 1024. M is a pre-defined integer and the M frames of the noise-reduced signal S3 correspond to the M frames of the downlink audio signal RX. Correspondingly, the decision unit 160 performs the decision method in FIG. 2 once per M frames of the signals S3 and RX. For purpose of clarity and ease of description, the following examples and embodiments are described with reference to M=1. However, any other integers for M are also applicable to the power estimation unit 150 and the decision method in FIG. 2.

FIG. 2 is a flow chart showing a decision method according to an embodiment of the invention. Referring to FIG. 2, the decision method performed by the decision unit 160 is described below.

Step S201: Set the gain value g of the multiplier 170 to a default value, such as 1, upon system initialization. Please note that step S201 is performed only once (i.e., upon system initialization), but steps S202-S210 are performed once per M frames (M=1) of the signals S3 and RX.

Step S202: Respectively receive two power levels Pt and Pr from the power estimation unit 150 per M frames (M=1) of the signals S3 and RX.

Step S204: Determine whether the power level Pt is greater than or equal to a first threshold value TH1. If YES, the flow goes to step S206; otherwise, the flow goes to step S208.

Step S206: Determine whether the power level Pr is greater than or equal to a second threshold value TH2. If YES, the flow goes to step S210; otherwise, the flow returns to step S202. Please note that the TH1 and TH2 values are independent and varied according to the mechanical defects of the communication device 10, such as the relative distance of the microphone 110 to the speaker 120, or the degree of gasket leaks. The condition “Pt>=TH1 and Pr<TH2” represents the near-end talker is speaking and the far-end talker is mute; the noise-reduced signal S3 is transmitted as the uplink audio signal TX to the far-end talker. Since the speaker 120 is mute, no acoustic echoes are produced. Accordingly, there is no need to modify the gain value g.

Step S208: Mute the uplink audio signal TX. The condition “Pt<TH1” indicates the power level Pt for a near-end talker is quite small and it is hard for the far-end talker to hear the near-end talker's voice. In this scenario, the decision unit 160 regards the near-end talker as “not speaking” and directly mutes the uplink audio signal TX by setting the values of the uplink audio signal TX to zero. The advantage of transmitting the mute uplink signal TX is preventing the far-end talker from hearing the echo of his own voice as he speaks.

Step S209: Reset the gain value g to the default value 1 as set in step S201. Then, the flow goes back to step S202.

Step S210: Reduce the gain value g. The condition “Pt>=TH1 and Pr>=TH2” is related to a double-talk case. The term “double-talk” refers to both the near-end and the far-end talkers speaking concurrently. The double-talk case includes two following scenarios: scenario A: Pr>Pt>=TH1; and, scenario B: Pt>=TH1 and Pr>=TH2. Scenario A represents the far-end talker speaks louder than the near-end talker. Scenario B represents the far-end talker does not necessarily speak louder than the near-end talker, but the power level Pr is relatively higher than TH2. In either scenario, the volume of the speaker 120 would be so high that the microphones 110 can easily pick up the speaker's output and create acoustic echoes. Thus, the gain value needs to be reduced to reduce the magnitudes of the echo signals received by the microphones 110. There are two approaches for reducing the gain value each time the condition “Pt>=TH1 and Pr>=TH2” is satisfied. Approach 1: a previous gain value g_{P} of the last round is multiplied by a constant number f1 to obtain a current gain value g_{C}, i.e., g_{C}=g_{P}×f1, where 0<f1<1. For example, f1=0.5. Approach 2: adjust the current gain value g_{C} according to the proportion of Pr to Prₘₐₓ, i.e., g_{C}=Pr/Prₘₐₓ, where Prₘₐₓ denotes the maximum power level per M frames of the downlink audio signal RX. For example, if Prₘₐₓ=100 and Pr=80, then the current gain value g_{C}=80/100=0.8. Theoretically, Approach 2 modifies the current gain value g_{C} according to the proportion of Pr to Prₘₐₓ, so the transition of the speaker volume is more smooth and the voice quality is better in comparison with Approach 1. After the gain value is reduced, residual echoes picked up by the microphones 110 and contained in the digital audio signal S1 would be also reduced. Afterward, it would be simple for the AEC unit 130 to eliminate the residual echoes in the digital audio signal S1, thus improving the quality and intelligibility of the uplink signal TX. Then, the flow backs to the step S202 and runs through the steps S202-S210 again for the following M frames of the signals S3 and RX.

Finally, the multiplier 170 is configured to multiply sample values of the following M frames of the downlink audio signal RX by the current gain value g_{C} to produce a gained audio signal S4. The speaker 120 then plays the gained audio signal S4.

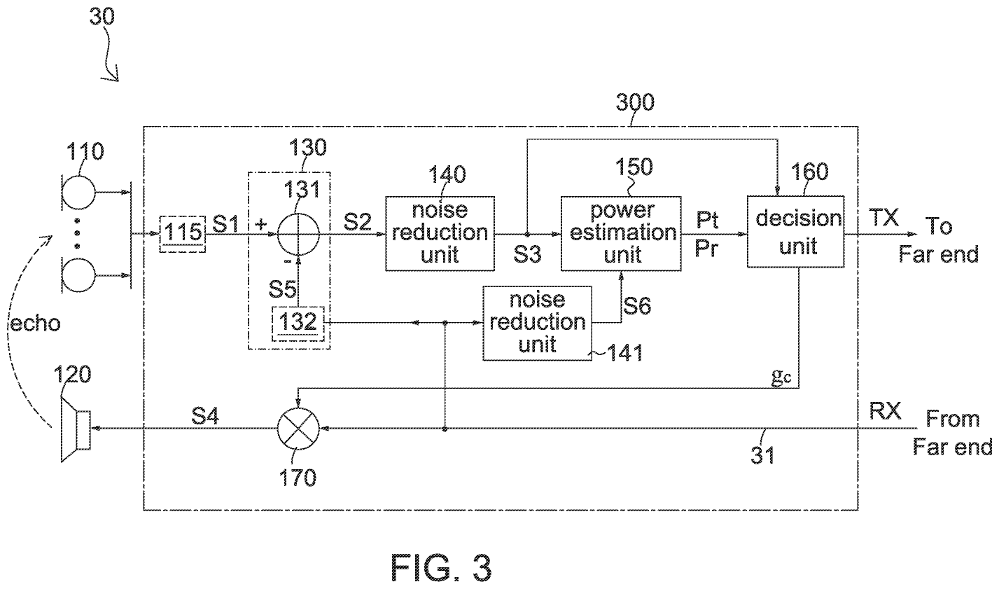

FIG. 3 is a schematic diagram showing a speech processing apparatus according to another embodiment of the invention. In comparison with FIG. 1, the speech processing apparatus 300, applicable to a communication device 30 with a mechanical defect, additionally includes a NR unit 141. Similar to the operations of the NR unit 140, the NR unit 141 is configured to reduce noise in the downlink audio signal RX to generate a noise-reduced signal S6 by any well-known NR algorithms, such as traditional NR algorithms or AI-NR. In this scenario, the power estimation unit 150 respectively calculates/estimates a power level Pt per M frames of the noise-reduced signal S3 and a power level Pr per M frames of the noise-reduced signal S6 according to the above power equation. The M frames of the noise-reduced signal S3 correspond to the M frames of the noise-reduced signal S6. The other operations of the speech processing apparatus 300 are the same as those of the speech processing apparatus 100. The NR unit 141 further eliminates the background noise in the downlink audio signal RX so as to avoid the downlink line 31 from being regarded as “busy”. Thus, the NR unit 141 assists the decision unit 160 in correctly determining the states (speaking or mute) of the far-end talker.

In summary, in a case that strong acoustic echoes are caused by mechanical defects or mechanical designs of the communication device 10/30 that are unlikely to be modified, the speech processing apparatus 100/300 of the invention can significantly reduce acoustic echoes for the far-end talker and improves the quality and intelligibility of the uplink audio signal TX.

In an embodiment, the speech processing apparatus 100/300 (excluding the ADC(s) in the pre-processing unit 115) is implemented with a general-purpose processor and a program memory. The program memory stores a processor-executable program. When the processor-executable program is executed by the general-purpose processor, the general-purpose processor is configured to function as: the pre-processing unit 115 (excluding the ADC(s)), the AEC unit 130, the NR units 140-141, the power estimation unit 150, the decision unit 160 and the multiplier 170.

The above embodiments and functional operations can be implemented in digital electronic circuitry, in tangibly-embodied computer software or firmware, in computer hardware, including the structures disclosed in this specification and their structural equivalents, or in combinations of one or more of them. The method and logic flow described in FIG. 2 can be performed by one or more programmable computers executing one or more computer programs to perform their functions. The method and logic flow in FIG. 2 can also be performed by special purpose logic circuitry, e.g., an FPGA (field programmable gate array) or an ASIC (application-specific integrated circuit). Computers suitable for the execution of the one or more computer programs include, by way of example, can be based on general or special purpose microprocessors or both, or any other kind of central processing unit. Computer-readable media suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto-optical disks; and CD-ROM and DVD-ROM disks.

While certain exemplary embodiments have been described and shown in the accompanying drawings, it is to be understood that such embodiments are merely illustrative of and not restrictive on the broad invention, and that this invention should not be limited to the specific construction and arrangement shown and described, since various other modifications may occur to those ordinarily skilled in the art.

What is claimed is:

1. A speech processing apparatus in a communication device having a mechanical defect, comprising:
an acoustic echo cancellation (AEC) unit configured to cancel an echo in a first audio signal from one or more microphones using a known AEC algorithm to generate a second audio signal;
a multiplier for multiplying a gain by corresponding M frames of a downlink audio signal to provide a gained downlink signal for a speaker; and
a processor configured to perform a set of operations comprising:
muting an uplink audio signal when a first power level for M frames of a first input signal associated with the second audio signal is less than a first threshold value; and
reducing the gain when the first power level is greater than or equal to the first threshold value and a second power level for M frames of a second input signal associated with the downlink audio signal is greater than or equal to a second threshold value, where M>=1.

2. The apparatus according to claim 1, wherein the set of operations further comprises:
reducing noise in the second audio signal using a first known noise reduction algorithm to generate a third audio signal;
wherein the first input signal is equal to the third audio signal.

3. The apparatus according to claim 1, wherein the set of operations further comprises:
reducing noise in the downlink audio signal using a second known noise reduction algorithm to generate a fourth audio signal;
wherein the second input signal is equal to the fourth audio signal.

4. The apparatus according to claim 1, wherein the set of operations further comprises:
when the first power level is greater than or equal to the first threshold value and the second power level is less than the second threshold value, keeping the gain unchanged.

5. The apparatus according to claim 1, wherein the operation of reducing the gain comprises:
obtaining a current gain g_{C} by the following equation: g_{C}=g_{P}×f1, where f1 is a constant number and 0<f1<1, and g_{P} denotes a previous gain.

6. The apparatus according to claim 1, wherein the operation of reducing the gain comprises:
adjusting the gain according to a proportion of Pr to Prₘₐₓ, where Pr and Prₘₐₓ respectively denote the second power level and the maximum power level for M frames of the second input signal.

7. The apparatus according to claim 1, wherein the mechanical defect is one of gasket leak and proximity of the one or more microphones to the speaker.

8. The apparatus according to claim 1, wherein the operation of muting the uplink audio signal further comprises:
resetting the gain to a default value as set during system initialization.

9. A speech processing method applicable to a communication device having a mechanical defect, comprising:
cancelling an echo in a first audio signal from one or more microphones using a known AEC algorithm to generate a second audio signal;
muting an uplink audio signal when a first power level for M frames of a first input signal associated with the second audio signal is less than a first threshold value;
reducing a gain when the first power level is greater than or equal to the first threshold value and a second power level for M frames of a second input signal associated with a downlink audio signal is greater than or equal to a second threshold value; and
multiplying the gain by corresponding M frames of the downlink audio signal to provide a gained downlink signal for a speaker, where M>=1.

10. The method according to claim 9, further comprising:
reducing noise in the second audio signal using a first known noise reduction algorithm to generate a third audio signal;
wherein the first input signal is equal to the third audio signal.

11. The method according to claim 9, further comprising:
reducing noise in the downlink audio signal using a second known noise reduction algorithm to generate a fourth audio signal;
wherein the second input signal is equal to the fourth audio signal.

12. The method according to claim 9, further comprising:
when the first power level is greater than or equal to the first threshold value and the second power level is less than the second threshold value, keeping the gain unchanged.

13. The method according to claim 9, wherein the step of reducing the gain comprises:
obtaining a current gain g_{C} by the following equation: g_{C}=g_{P}×f1, where f1 is a constant number and 0<f1<1, and g_{P} denotes a previous gain.

14. The method according to claim 9, wherein the step of reducing the gain comprises:
adjusting the gain according to a proportion of Pr to Prₘₐₓ, where Pr and Prₘₐₓ respectively denote the second power level and the maximum power level for M frames of the second input signal.

15. The method according to claim 9, wherein the mechanical defect is one of gasket leak and proximity of the one or more microphones to the speaker.

16. The method according to claim 9, wherein the step of muting the uplink audio signal further comprises:
resetting the gain to a default value as set during system initialization.
